(19) United States
(12) Patent Application Publication
(10) Pub. No.: US 2010/0006962 A1
(43) Pub. Date: Jan. 14, 2010

(54) Method of manufacturing a porous structure

(75) Inventor: Kazuhide Abe, Tokyo (JP)

Correspondence Address: RABIN & Berdo, PC, 1101 14TH STREET, NW, SUITE 500, WASHINGTON, DC, 20005, US

(73) Assignee: OKI SEMICONDUCTOR CO., LTD., Tokyo (JP)

(21) Appl. No.: 12/458,188

(22) Filed: Jul. 2, 2009

(30) Foreign Application Priority Data
Jul. 3, 2008 (JP) 2008-174467

(51) Int. Cl. H01L 31/02; H01L 21/30

(52) U.S. Cl. 257/431; 438/700; 257/E21.211; 257/E31.11

(57) ABSTRACT

Disclosed is a method for fabrication of a porous structure that can prevent release of a protective layer from a semiconductor substrate even if a liquid chemical is used during an anodic oxidation process. The method includes forming an oxide layer on an upper face of the semiconductor substrate. The semiconductor substrate has a diffusion layer in its upper face. The method also includes forming a plurality of contact holes at desired positions of the oxide layer. The method also includes forming a wire in each of the contact holes, and forming an opening between wires to expose a surface of the diffusion layer. The method also includes forming a drain on a peripheral circumference of the opening and depositing a protective film over an entire upper part of the substrate. The protective film fills the drain. The method also includes removing most of the protective film from the opening while leaving behind a part of the protective film on the peripheral circumference of the opening and exposing a certain portion of the diffusion layer. The method also includes applying an anodic oxidation process to the exposed diffusion layer using the remaining protective film as a protective layer.

### BACKGROUND OF THE INVENTION

1. Field of the Invention

The present invention relates to a method of manufacturing a porous structure and, more particularly, a method of fabricating a porous structure in a semiconductor substrate by anodic oxidation.

2. Description of the Related Art

If silicone used for a semiconductor integrated circuit becomes microfine (e.g., to a nanometer level), it provides a variety of quantum phenomena. One of such phenomena is light emission. Because nano-size silicon can emit light, it can be used for a light emitting diode and other applications including, for example, an optical waveguide and an optical cavity (resonator). Thus, the use of nano-size silicon is extended to an optical integrated circuit (see Japanese Patent Application Kokai (Laid-open) No. 2006-343671). A nano-porous Si structure formed by making nano-sized holes in silicon can serve as a non-volatile optical memory. Because of quantum confinement effects, the nano-porous Si structure may function as an electrical/optical memory. Moreover, nano-porous silicon structure has a thermal conductivity that is only about 1/170th that of bulk silicon. Thus, silicon is expected to be used as an ultrasonic source (see Japanese Patent Application Kokai No. 2005-73197).

The nano-porous Si structure may be fabricated by anodic oxidation and such anodic oxidation may also be used to form an insulating layer on a gate electrode in order to offset an impurity region of a thin film transistor by a certain distance from the gate electrode (see Japanese Patent Application Kokai No. 5-206465).

### SUMMARY OF THE INVENTION

When a nano-porous structure is formed on a semiconductor substrate, it may be necessary to form a wiring layer on the substrate in order to allow the porous structure to be conduction-connected with an electrode of an anodic oxidation apparatus. It may also be necessary to remove an insulating layer (i.e., a protective film) covering a wire in order to expose a particular part of the semiconductor substrate. The exposed part is subsequently subject to anodic oxidation. In the anodic oxidation process, which uses a liquid chemical (e.g., fluoric acid), the exposed part may contact the liquid chemical since an interface between the substrate and the protective film is exposed. The liquid chemical sinks (penetrates) into that portion of the substrate/protective film interface which has a low adhesiveness, thus causing release of the protective film from the substrate. If this penetration of the liquid chemical proceeds, the liquid chemical may etch an oxide layer below the protective film or the wire. This results in the oxide layer being released from the substrate.

One object of the present invention is to provide a method for fabrication of a porous structure that has no release (or a very limited release) of a protective film from a semiconductor substrate even if a liquid chemical is used for anodic oxidation.

It has been found that the above-described problems are solved by the porous structure fabrication method of the present invention.

According to a first aspect of the present invention, there is provided a method for fabricating a porous structure, including the step of providing a semiconductor substrate having a diffusion layer. The diffusion layer may be embedded in an upper face of the semiconductor substrate. The fabrication method also includes the step of forming an oxide layer on the upper face of the semiconductor substrate, and the step of forming a plurality of contact holes at desired positions of the oxide layer. The fabrication method also includes the step of forming a wire in each of the contact holes, and the step of forming an opening between the wires to expose a surface of the diffusion layer. The fabrication method also includes the step of forming a drain (groove) on a peripheral circumference (outer periphery) of the opening and the step of depositing a protective film over an entire upper part of the substrate, so as to fill the drain. The fabrication method also includes the step of removing most of the protective film while leaving behind a certain part of the protective film on the peripheral circumference of the opening. The fabrication method also includes the step of exposing the diffusion layer, and the step of applying the anodic oxidation process to the exposed diffusion layer using the remaining protective film (or the left-behind protective film) as a protective layer.

According to the porous structure fabrication method of the present invention, it is possible to reduce or prevent release (detachment) of the protective film from the semiconductor substrate even if a liquid chemical is used in the anodic oxidation process.

According to a second aspect of the present invention, there is provided another method for fabricating a porous structure. This fabrication method includes the step of providing a semiconductor substrate having a diffusion layer. The fabrication method also includes the step of forming a drain (groove) around an anodic oxidation region of a semiconductor substrate. The anodic oxidation region is a region to which the anodic oxidation process will be applied later. The fabrication method also includes the step of forming a protective part in the drain, and the step of forming an oxide layer over an entire upper part of the substrate. The fabrication method also includes the step of forming a plurality of contact holes in the oxide layer except for the anodic oxidation region and the step of forming a wire in each of the contact holes. The fabrication method also includes the step of forming an opening in the anodic oxidation region to expose a surface of the diffusion layer and the step of depositing a protective film over an entire upper part of the substrate. The protective film fills the opening. The fabrication method also includes the step of removing most of the protective film from the opening while leaving behind a certain part of the protective film on a peripheral circumference of the opening, and the step of exposing the diffusion layer. The fabrication method also includes the step of applying the anodic oxidation process to the exposed diffusion layer using the remaining protective film as a protective layer.

The porous structure fabrication method of the present invention can reduce or prevent release (detachment) of the protective film from the semiconductor substrate even if a liquid chemical is used in the anodic oxidation process.

### BRIEF DESCRIPTION OF THE DRAWINGS

The above and other objects, aspects, features and advantages of the present invention will become clear from the following detailed description when read and understood in conjunction with the accompanying drawings, in which:

FIG. 1A to 1D and FIG. 2E to 2H are a series of cross-sectional views illustrating a method for fabrication of a porous structure according to a first exemplary embodiment of the present invention;

FIG. 3A to 3D and FIG. 4E to 4H are a series of top views which correspond to FIG. 1A to 1D and FIG. 2E to 2H, respectively;

FIG. 5 is a schematic cross-sectional view illustrating an anodic oxidation apparatus;

FIG. 6 is a diagram useful to explain a supercritical fluid;

FIG. 7A to 7E and FIG. 8F to 8I are a series of cross-sectional views illustrating a method for fabrication of a porous structure according to a second exemplary embodiment of the present invention;

FIG. 9A is an SEM image showing a top view of an infrared detection device;

FIG. 9B is an enlarged perspective SEM image of an area A in FIG. 9A; and

FIG. 9C is an enlarged SEM image of an area B in FIG. 9B.

### DETAILED DESCRIPTION OF THE INVENTION

Hereinafter, exemplary embodiments of the present invention will be described in greater detail with reference to the accompanying drawings. In the drawings, shapes and sizes of constructional parts and arrangement thereof are schematically illustrated only in order to facilitate understanding of the present invention, but a person skilled in the art will appreciate that the present invention is not restricted thereto.

### First Embodiment

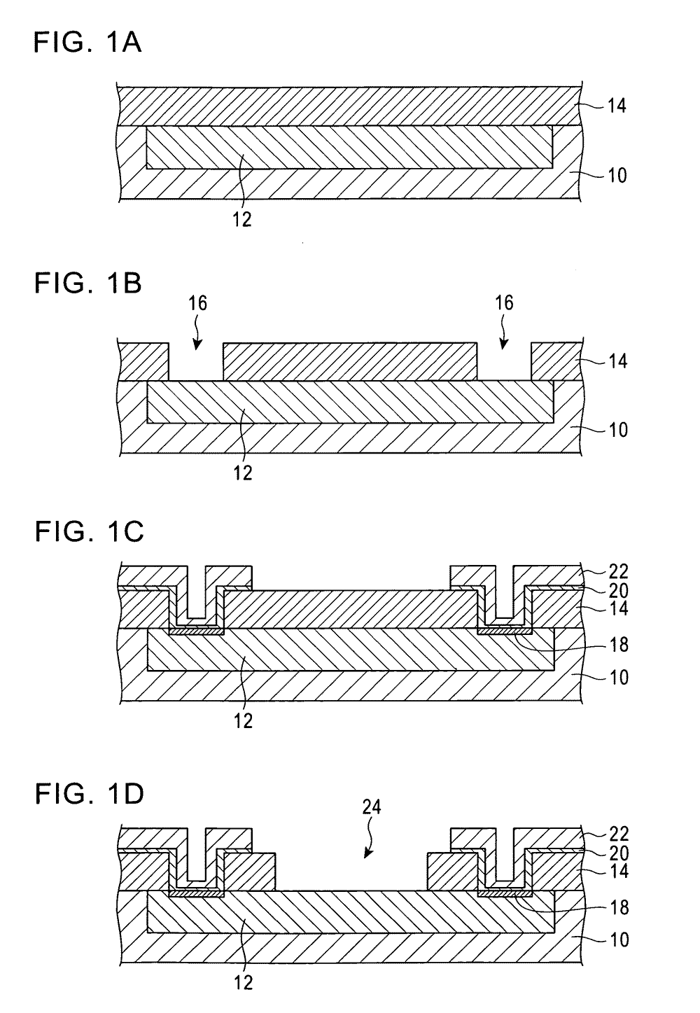

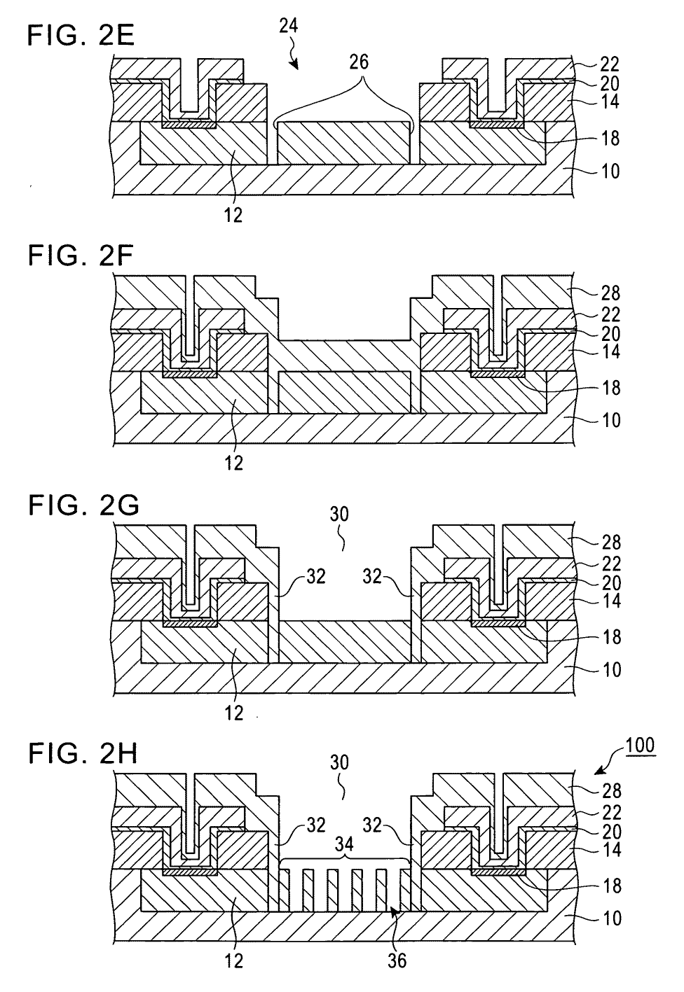

FIG. 1A to 1D and FIG. 2E to 2H are a series of cross-sectional views illustrating a method for fabrication of a porous structure according to a first embodiment of the present invention. FIG. 3A to 3D and FIG. 4E to 4H are top views illustrating the porous structure fabrication method, which correspond to FIG. 1A to 1D and FIG. 2E to 2H, respectively.

(i) Formation of an oxide layer on a semiconductor substrate having a diffusion layer

First, as illustrated in FIG. 1A and FIG. 3A, a semiconductor substrate 10 is prepared. A diffusion layer 12 doped with B or P is formed on (in) a desired surface area of the semiconductor substrate 10. The doping of B or P is performed by a known implantation process.

Then, an oxide layer 14 with a certain film thickness is formed on the semiconductor substrate 10 by thermal oxidation or spin coating. The oxide layer 14 is made of, for example, SiO₂.

(ii) Formation of a plurality of contact holes at desired positions of the oxide layer, formation of a wire in each of the contact holes, and formation of an opening between the wires to expose a surface of the diffusion layer

As illustrated in FIG. 1B and FIG. 3B, a plurality of contact holes 16 are formed at desired positions of the oxide layer 14 by means of a common lithography and etching process. The contact holes 16 are positioned around an anodic oxidation region (will be described below). Wiring is made in the contact holes such that the wiring will be connected to electrodes of an anodic oxidation apparatus.

Then, as illustrated in FIG. 1C and FIG. 3C, a barrier metal layer 20 with a TiN or Ti laminate structure is deposited in the contact holes 16 and on (over) the oxide layer 14 in the vicinity of the contact holes 16 by, for example, sputtering. Such barrier metal layer 20 may function to reduce or prevent diffusion of a wiring material (will be described) toward the diffusion layer 12. In addition, forming a TiN layer over a Ti layer as described above may inhibit oxidation of Ti.

Subsequently, in order to conduction-connect the diffusion layer 12 with the wiring (will be described), the substrate 10 is heated at about 800° C. for a short time (about 30 seconds) in an inert atmosphere such as N₂ and Ar so that a silicide layer 18 made from titanium silicide (e.g., TiSi₂) is formed at an interface of the barrier metal layer 20 and the diffusion layer 12.

Then, a metal layer made from Al, Cu or the like (not shown) is deposited on the substrate 10 by sputtering, and wiring 22 is formed by conventional lithography and etching.

As illustrated in FIG. 1D and FIG. 3D, an opening 24 is formed on an area between the wiring 22 to expose a surface of a particular part of the diffusion layer 12. This area will be used for anodic oxidation (will be described below).

(iii) Formation of a drain (groove) along a peripheral circumference (wall) of the opening and deposition of a protective film in the drain and over an entire upper side of the substrate

As illustrated in FIG. 2E and FIG. 4E, in order to expose the peripheral circumference of the opening 24, a mask (not shown) is provided on the opening 24. The mask may be a resist.

Then, dry etching is performed using an HBr/O₂ gas mixture as a process gas at a pressure of 5 mTorr and a gas flow rate of 100/1 sccm to form a drain 26 in the diffusion layer 12. Thereafter, the mask (not shown) is removed by etching.

A depth of the drain 26 is not particularly restricted so long as an interface between the diffusion layer 12 and the oxide layer 14 is substantially sealed by a protective film (will be described).

As illustrated in FIG. 2F and FIG. 4F, in order to fill the drain 26, a protective film 28 is formed over an entire upper side of the semiconductor substrate 10. Such protective film 28 may function to prevent the wire 22 and/or the interface between the diffusion layer 12 and the oxide layer 14 from being exposed to a liquid chemical used during the anodic oxidation process.

As understood from the foregoing, a film thickness of the protective film 28 is not particularly restricted so long as the wire 22 and/or the diffusion layer-oxide layer interface can be protected from the liquid chemical used during the anodic oxidation process.

The protective film 28 is preferably made from SiC. SiC may be formed by plasma CVD. SiC may be formed at a temperature equal to or less than a melting point of Cu or Al. Cu and Al are commonly used as a wire material.

(iv) Removal of most of the protective film while leaving behind a certain part of the protective film on the peripheral circumference of the opening and exposure of the diffusion layer

As illustrated in FIG. 2G and FIG. 4G, the protective film 28 deposited on the opening 24 is removed by conventional lithography and etching in a manner such that a predetermined part of the protective film 28 is left behind along a peripheral circumference of the opening 24. The left-behind protective film 28 is referred to as a protective layer 32. As a result, a surface of the diffusion layer 12 is exposed and an opening 30 for anodic oxidation is formed.

The protective layer 32 covers the interface between the diffusion layer 12 and the oxide layer 14, so that the covered interface is not exposed to the liquid chemical used during the anodic oxidation. The interface between the diffusion layer 12 and the oxide layer 14 is a contact face between different materials, thus having relatively low adhesiveness. Therefore, covering the diffusion layer-oxide layer interface with the protective layer 32 can prevent the liquid chemical from reaching the interface and can prevent disconnection (detachment) of the oxide layer 14 from the diffusion layer 12 that would otherwise occur at the interface.

As described above, a thickness of the protective layer 32 is not particularly restricted, but must be sufficient to protect the interface between the diffusion layer 12 and oxide layer 14 from the liquid chemical and to protect the wiring 22 from the liquid chemical.

(v) Treatment of the exposed diffusion layer by anodic oxidation using the remaining protective layer as a protective film

Lastly, as illustrated in FIG. 2H and FIG. 4H, anodic oxidation is performed in the liquid chemical containing fluoric acid HF to form nano-sized holes 36 in an anodic oxidation part 34 of the diffusion layer 12 of the semiconductor substrate 10.

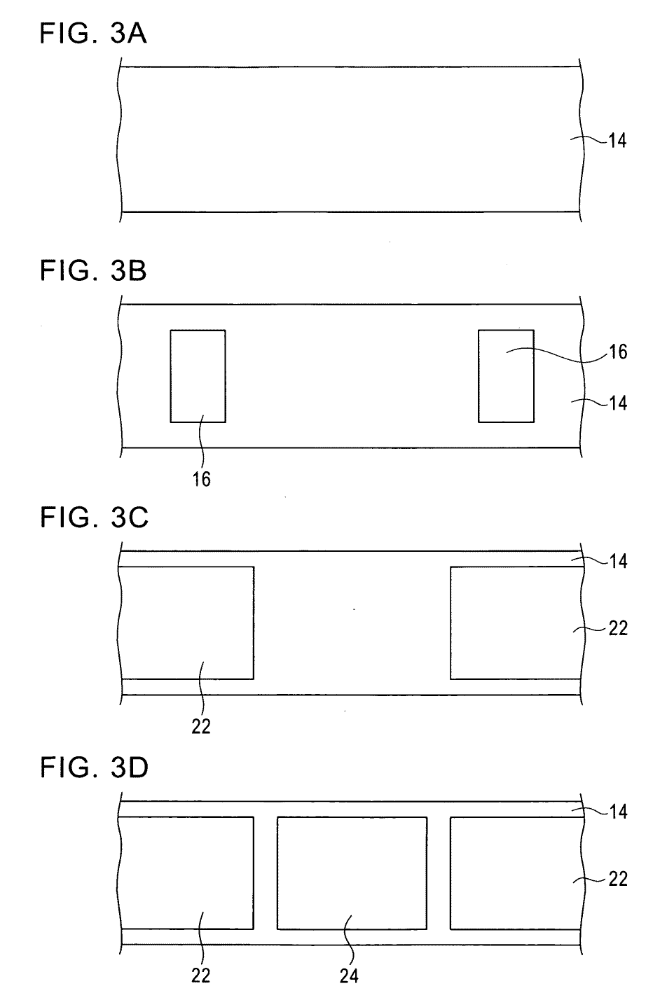

Such anodic oxidation may be performed using an anodic oxidation apparatus 200 as shown in FIG. 5. As illustrated in FIG. 5, the semiconductor substrate 10 shown in FIG. 2G and FIG. 4G is prepared and the HF solution 46 is poured into a container. The wall of the container is defined by a Teflon (registered trademark) cell 44 and O-ring 42. Then, each wire 22 is connected to an associated electrode 40 and an opposite electrode 48 is placed in the HF solution 46 such that the electrode 48 faces the substrate 10.

Afterward, using the semiconductor substrate 10 as an anode, a particular part of the diffusion layer 12 formed on the substrate 10 is oxidized, and oxidized parts are removed therefrom. As a result, a plurality of holes 36 are formed as shown in FIG. 2H and FIG. 4H. During the anodic oxidation process, a magnet is preferably placed to sandwich (confine) the semiconductor substrate 10 and the opposite electrode 48 such that the anodic oxidation is performed in a magnetic field of about 2T. Such anodic oxidation performed in the magnetic field may form a deep(er) hole 36 with reduced diameter.

The holes 36 may or may not have a depth to penetrate through the diffusion layer 12. A density of the holes 36 in the diffusion layer 12 (i.e., porosity) may be suitably adjusted based on conditions of the anodic oxidation. More particularly, decreasing a concentration of HF and increasing a current density in the anodic oxidation process may increase the porosity.

When the HF concentration and/or current density are significantly decreased and/or increased, it may create conditions for electrolytic polishing and consequently nano-sized holes may not be formed. Hence, it may be required to appropriately control treatment conditions (i.e., anodic oxidation conditions). If the holes 36 are formed in a crossbeam of an infrared detection device (will be described), a yield may be enhanced (improved) because downsizing of such infrared detection device is achieved and the crossbeam structure is simplified. This will be described later.

Preferably, the porous structure manufacturing method of this embodiment may include washing the holes 36 using a supercritical fluid after forming the holes 36 through the anodic oxidation.

Increased porosity may reduce a thickness of a wall of each hole 36 and may weaken a framework structure of the anodic oxidation part 34. If it occurs, the holes 36 may be broken by a surface tension of the liquid chemical during or after the anodic oxidation. That is, the porosity of the holes 36 formed in the liquid chemical could be reduced when the liquid chemical is washed out outside the liquid chemical container. Hence, in order to maintain a desired porosity, the holes 36 are preferably rinsed using a supercritical fluid, and the liquid chemical is dried and removed.

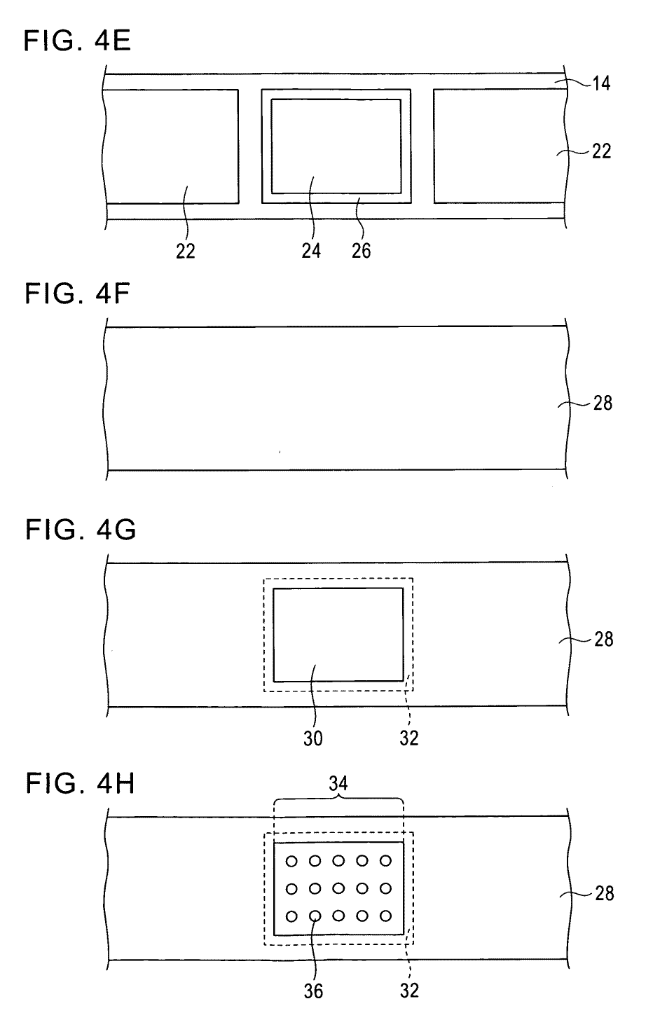

As illustrated in FIG. 6, the supercritical fluid refers to a state wherein a pressure and a temperature are not less than a critical pressure Pc and a critical temperature Tc, respectively (a shaded part FIG. 6). It is known that supercritical fluids have intermediate characteristics between a liquid and a gas, thus being efficiently used in precision removal of impurities and/or washing. More particularly, supercritical fluids have a density substantially comparable to that of a liquid and a higher solubility so that they can effectively remove or wash out a liquid chemical. At the same time, supercritical fluids exhibit good diffusibility like a gas, thus evenly removing or washing out the liquid chemical within a short period of time. In addition, like a gas, the supercritical fluids have a low viscosity so that they can sufficiently rinse a microfine part or a micro structure.

Examples of materials capable of being converted into a supercritical fluid include carbon dioxide, methane trifluoride, ethane, propane, butane, benzene, methylether, chloroform, water, ammonia, ethanol and nitrogen oxides. Among these, carbon dioxide is preferable because its critical pressure Pc is about 7.4 MPa and its critical temperature Tc is about 31° C. In other words, carbon oxide has a critical point in a practical range. Also, carbon dioxide is non-toxic and inexpensive.

It should be noted that a sub-critical fluid present in an area just before the critical point C (FIG. 6) may also be used. The fluid in this area is sometimes distinguished from the supercritical fluid. However, since physical properties of the fluid such as density are continuously varied, there is no substantial physical boundary between the supercritical fluid and the sub-critical fluid. Hence, the sub-critical fluid may be used instead of the supercritical fluid. A material present in a sub-critical area and/or a supercritical area closer to the critical point C may be called a high-density liquefied gas.

### Second Embodiment

Another method for fabrication of a porous structure, according to a second embodiment of the present invention, will be described below. The second embodiment is different from the first embodiment in that the second embodiment includes formation of a protective part in a diffusion layer before forming an oxide layer.

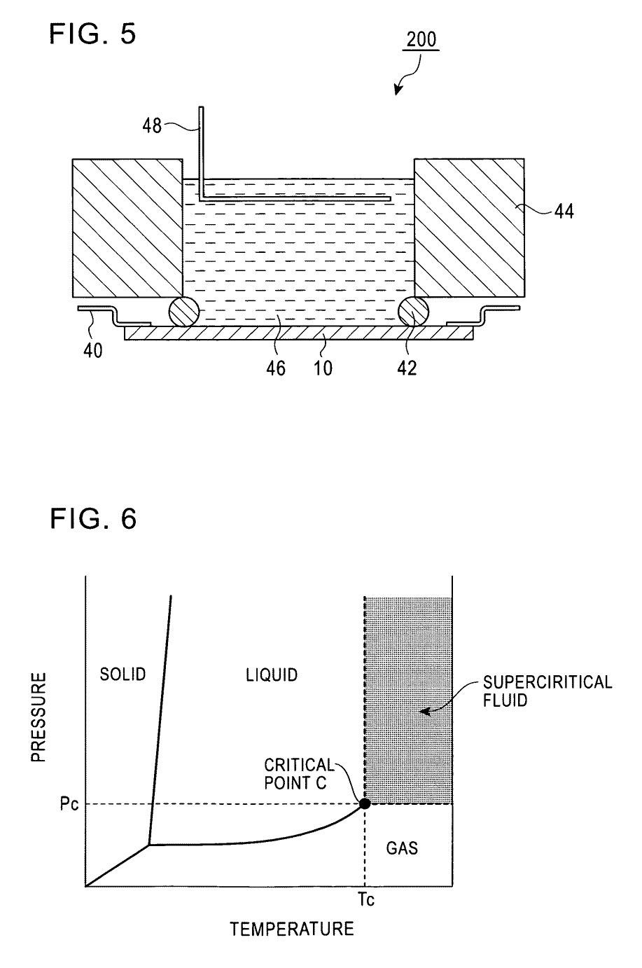

The method for fabrication of a porous structure according to the second embodiment of the present invention will be described with reference to FIG. 7A to 7E and FIG. 8F to 8I. Detailed description of the same processes as in the first embodiment will be omitted in the following description.

(i) Formation of a drain (groove) around an anodic oxidation region of a semiconductor substrate having a diffusion layer and formation of a protective part in the drain

First, as illustrated in FIG. 7A, a diffusion layer 52 is formed on a semiconductor substrate 50. Then, as illustrated in FIG. 7B, a drain 51 is formed, which surrounds a region 74. The region 74 will undergo anodic oxidation (hereinafter, referred to as “an anodic oxidation part”). A process of forming the drain 51, a width of the drain 51, and the diffusion layer 52 are substantially identical to those described in the first embodiment.

Following this, as illustrated in FIG. 7C, a protective film (not shown) is provided over an entire upper part (upper face) of the substrate 50. The drain (groove) 51 is filled with the protective film. Then, the protective film deposited on an area except for the drain 51 is removed by etching to obtain a protective part 53. Such protective part 53 is preferably formed using the same material as the material used for a protective layer (will be described). If the materials are different, an interface between the protective part 53 and the protective layer may have reduced adhesiveness and a liquid chemical of the anodic oxidation may sink (penetrate) into the interface. Materials of the protective part 53 are identical to those described in the first embodiment.

(i) Formation of an oxide layer over an entire upper part (upper surface) of the semiconductor substrate

Next, as illustrated in FIG. 7D, an oxide layer 54 is formed over an entire upper part (upper face) of the semiconductor substrate 50. The oxide layer 54 is substantially identical to that described in the first embodiment.

(ii) Formation of a plurality of contact holes in an area of the oxide layer except for the anodic oxidation region, formation of a wire in each of the contact holes, and formation of an opening in the anodic oxidation region to expose a desired surface of the diffusion layer

Subsequently, as illustrated in FIG. 7E, a plurality of contact holes are formed in an area except for the anodic oxidation part 74 of the oxide layer 54. In each of the contact holes, a silicide layer 58, a barrier metal layer 60 and a wire 62 are provided. Processes for formation of the silicide layer 58, the barrier metal layer 60 and the wire 62 as well as materials thereof are substantially identical to those described in the first embodiment.

Then, as illustrated in FIG. 8F, an opening (hole) 64 is formed in order to expose a part of the protective part 53 as well as the anodic oxidation part 74. A width x between the oxide layer 54 constructing an inner wall of the opening 64 and a face of the protective part 53 at the anodic oxidation part 74 side corresponds to a thickness of the protective layer (will be described). Hence, the width x is not particularly restricted so long as the width x is sufficient to withstand a liquid chemical used in the anodic oxidation process.

The protective part 53 has a width y. The relationship between the width x and width y of the protective part 53 is preferably represented by x/y<1. A construction satisfying this relationship is illustrated in FIG. 8F. That is, the oxide layer 54 preferably covers (extends over) a part of the surface of the protective part 53. As illustrated in FIG. 8H, an etched protective layer 72 on the protective part 53 forms an interface using the same material as that used for the protective part 53. Thus, it is possible to minimize penetration of the liquid chemical of the anodic oxidation process into the interface between the protective part 53 and the protective layer 72. As a result, the liquid chemical hardly reaches the oxide layer 54 and the diffusion layer 52.

(iii) Deposition of a protective film over an entire upper part of the semiconductor substrate to fill the opening
(iv) Removal of most of the protective film from the opening while leaving behind a certain part of the protective film on a peripheral circumference of the opening, and exposure of the diffusion layer
(v) Treatment of the exposed diffusion layer by anodic oxidation using the protective film remaining in the opening

These processes (iii) to (v) are the same as the corresponding processes in the first embodiment (FIG. 2E to 2H). Hence, detailed explanation thereof will be omitted here.

As is apparent from the above description, the method for fabrication of a porous structure according to the present invention provides a porous structure having a plurality of holes on a semiconductor substrate without release (detachment) of an oxide layer from the semiconductor substrate due to the anodic oxidation.

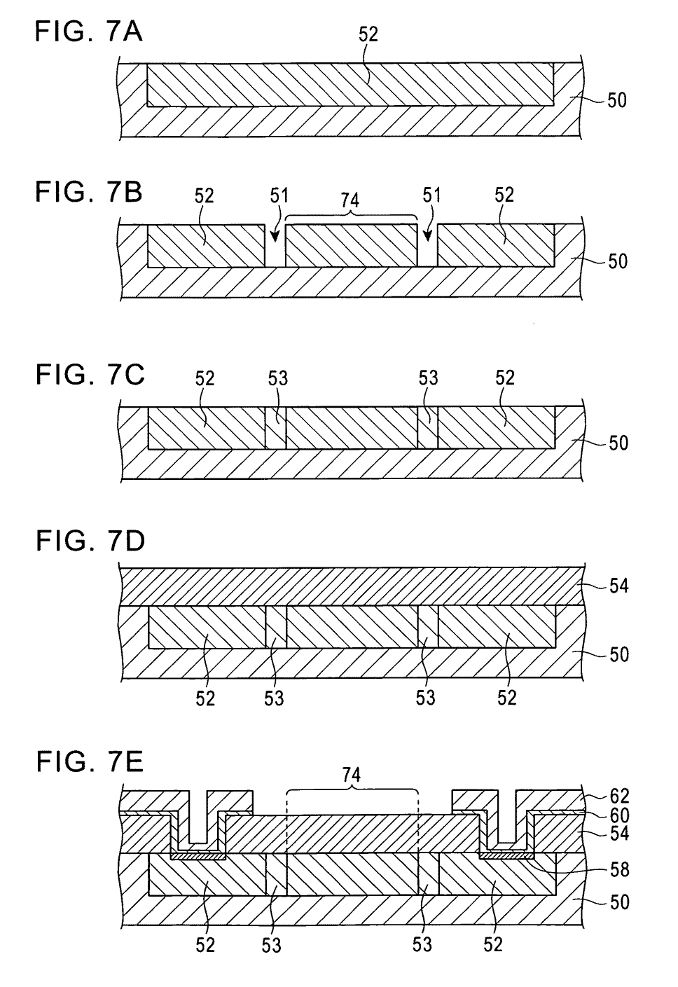

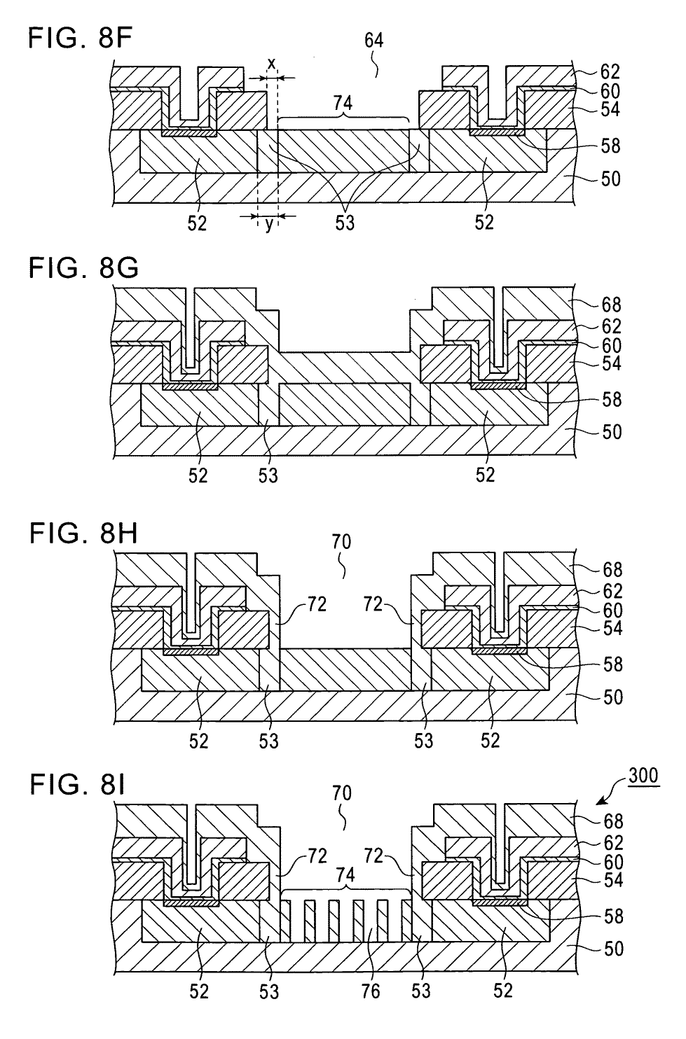

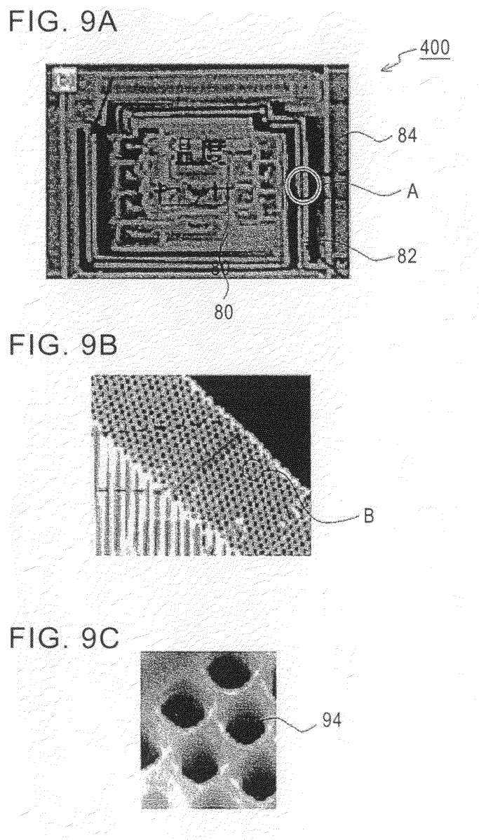

Such porous structure may be used for various devices including, for example, a photonic crystal device (e.g., a wavelength transformation device, a sum/difference frequency generation device and an OPA device), and a sonic generation instrument (e.g., an actuator, an ultrasonic source and a loudspeaker audio source). Especially, the porous structure may be employed in an infrared detection device. A detailed description will be given of the infrared detection device having the porous structure of this invention with reference to FIG. 9A to 9C.

### Infrared Detection Device

FIG. 9A is an SEM photograph showing an upper face of an infrared detection device, FIG. 9B is an enlarged perspective SEM photograph showing an area A in FIG. 9A, and FIG. 9C is an enlarged SEM photograph showing an area B in FIG. 9B.

The infrared detection device 400 shown in FIG. 9A includes an infrared light receiving part 80. The infrared light receiving part 80 is connected to a substrate 84 by a crossbeam 82. The infrared detection device 400 detects heat and temperature with a PN diode. The infrared detection device 400 is a thermoelectricomotive type. The infrared light receiving part 80 has a hole (or a cavity or a recess) formed in its lower face. Hence, the substrate 84 is not directly in contact with the infrared light receiving part 80. Accordingly, the infrared light receiving part 80 is insulated by atmosphere and is able to efficiently sense heat generated by the infrared rays.

The infrared detection device 400 of the thermoelectromotive type may have a narrow(er) and elongated crossbeam 82 to reduce emission of heat generated from the infrared light receiving part 80 because the narrow and elongated crossbeam may improve detection sensitivity of the device 400. The porous structure fabricated by the method of the invention may be used in the crossbeam in order to further reduce emission of heat. In other words, forming a plurality of holes on the crossbeam 8 may reduce heat transfer in the crossbeam 8.

It should be noted that many holes formed on the crossbeam may reduce conductivity of the crossbeam, and data (or information) detected (or obtained) by the infrared light receiving part may become difficult to transmit to the outside. However, specific physical properties of the nano-sized holes can reduce the drop in conductivity.

An exemplary construction of the crossbeam has the porous structure as shown in FIG. 9B, and holes 94 of the porous structure are shown in FIG. 9C in the greater scale. These holes 94 are arranged on the crossbeam. A number of holes 94 decrease (suppress) the heat emission from the infrared light receiving part 80 without adversely affecting information transmission from the infrared light receiving part 80.

The infrared detection device 400 having the crossbeam constructed as described above has reduced thermal conductivity in the crossbeam. Thus, the device 400 does not need a long crossbeam. Hence, space for placing the crossbeam may be decreased. Consequently, downsizing of the infrared detection device 400 can be achieved. In addition, a shape of the crossbeam can be simplified. This improves the yield.

Although the preferred embodiments of the present invention has been disclosed for illustrative purposes, those skilled in the art will appreciate that various changes, modifications, additions and substitutions are possible to the illustrated embodiments, without departing from the scope and spirit of the invention as disclosed in the appended claims.

This application is based on Japanese Patent Application No. 2008-174467 filed on Jul. 3, 2008, and the entire disclosure thereof is incorporated herein by reference.

What is claimed is:

1. A method for fabrication of a porous structure, comprising:
providing a semiconductor substrate having a diffusion layer;
forming an oxide layer on an upper face of the semiconductor substrate;
forming a plurality of contact holes at predetermined positions of the oxide layer;
forming a wire in each of the plurality of contact holes;
forming an opening at an area between the wires to expose a predetermined surface part of the diffusion layer;
forming a drain in the exposed diffusion layer along a peripheral circumference of the opening;
depositing a protective film over an entire upper part of the substrate such that the drain is filled with the protective film, the opening is at least partly filled with the protective film and the wire is covered with the protective film;
removing the protective film from the opening while leaving behind a predetermined part of the protective film on the peripheral circumference of the opening and exposing the diffusion layer; and
applying an anodic oxidation process to the exposed diffusion layer using the left-behind protective film as a protective layer.

2. The method for fabrication of a porous structure according to claim 1, wherein the protective layer comprises SiC.

3. The method for fabrication of a porous structure according to claim 1, further comprising washing the diffusion layer, which has undergone the anodic oxidation process, with a supercritical fluid or an equivalent fluid.

4. The method for fabrication of a porous structure according to claim 1, further comprising providing a barrier metal layer in each of the plurality of contact holes prior to the forming of the wire.

5. The method for fabrication of a porous structure according to claim 4, further comprising providing a silicide layer between the barrier metal layer and the diffusion layer prior to the forming of the wire.

6. The method for fabrication of a porous structure according to claim 1, wherein the anodic oxidation process creates a plurality of nano-size holes in the diffusion layer.

7. The method for fabrication of a porous structure according to claim 1, wherein the anodic oxidation process is carried out in a magnetic field environment.

8. A method for fabrication of a porous structure, comprising:
providing a semiconductor substrate having a diffusion layer;
defining an anodic oxidation region on an upper face of the semiconductor substrate;
forming a drain around the anodic oxidation region;
forming a protective part in the drain;
forming an oxide layer over an entire upper part of the semiconductor substrate;
forming a plurality of contact holes in the oxide layer except for the anodic oxidation region;
forming a wire in each of the contact holes;
forming an opening in the anodic oxidation region to expose a predetermined surface portion of the diffusion layer;
depositing a protective film over the entire upper part of the substrate such that the protective film fills the opening;
removing the protective film from the opening while leaving behind a predetermined part of the protective film on a peripheral circumference of the opening, and exposing the diffusion layer; and
applying an anodic oxidation process to the exposed diffusion layer using the left-behind protective film as a protective layer.

9. The method for fabrication of a porous structure according to claim 8, wherein the protective layer comprises SiC.

10. The method for fabrication of a porous structure according to claim 8, further comprising washing the diffusion layer, which has undergone the anodic oxidation process, with a supercritical fluid.

11. The method for fabrication of a porous structure according to claim 8, further comprising providing a barrier metal layer in each of the plurality of contact holes prior to the forming of the wire.

12. The method for fabrication of a porous structure according to claim 11, further comprising providing a silicide layer between the barrier metal layer and the diffusion layer prior to the forming of the wire.

13. The method for fabrication of a porous structure according to claim 8, wherein the anodic oxidation process creates a plurality of nano-size holes in the diffusion layer.

14. The method for fabrication of a porous structure according to claim 8, wherein the anodic oxidation process is carried out in a magnetic field environment.

15. The method for fabrication of a porous structure according to claim 8, wherein the protective part is made from the same material as the protective film.

16. The method for fabrication of a porous structure according to claim 8, wherein the protective film has a width less than a width of the protective part.

17. An infrared detection device comprising:
an infrared light receiving part;
a substrate; and
a crossbeam for connecting the infrared light receiving part with the substrate, wherein the crossbeam has a porous structure made by the method of claim 1.

18. An infrared detection device comprising:
an infrared light receiving part;
a substrate; and
a crossbeam for connecting the infrared light receiving part with the substrate, wherein the crossbeam has a porous structure made by the method of claim 8.
